(19) United States
(12) Patent Application Publication
(10) Pub. No.: US 2012/0276746 A1
(43) Pub. Date: Nov. 1, 2012

(54) MANUFACTURING METHOD OF SEMICONDUCTOR DEVICE AND APPARATUS FOR MANUFACTURING SEMICONDUCTOR DEVICE

(75) Inventors: Yuji HIKIDA, Nagoya-city (JP); Kouichi Miyashita, Nishio-city (JP)

(73) Assignee: DENSO CORPORATION, Kariya-city (JP)

(21) Appl. No.: 13/095,048

(22) Filed: Apr. 27, 2011

(51) Int. Cl. H01L 21/3065; C23F 1/08

(52) U.S. Cl. 438/706; 156/345.1; 156/345.33; 156/345.37; 257/E21.218

(57) ABSTRACT

A manufacturing method for a semiconductor device includes: arranging a plurality of silicon substrates having a sacrifice layer in a reaction chamber in such a manner that surfaces of silicon substrates face each other; introducing an etching gas into the reaction chamber; reacting the etching gas and the sacrifice layer in each silicon substrate so that the sacrifice layer is dry-etched; and arranging a partition member in the reaction chamber to partition a predetermined range between adjacent silicon substrates. The partition member has a property in such a manner that a water molecule hardly penetrates the partition member. The water molecule is a reaction product between the etching gas and the sacrifice layer.

### CROSS REFERENCE TO RELATED APPLICATION

This application is based on Japanese Patent Application No. 2009-252005 filed on Nov. 2, 2009, the disclosure of which is incorporated herein by reference.

### TECHNICAL FIELD

The present invention relates to a manufacturing method of a semiconductor device having a silicon substrate with a sacrifice layer and apparatus for manufacturing a semiconductor device having a silicon substrate with a sacrifice layer.

### BACKGROUND

Conventionally, a method for dry-etching a sacrifice layer of a silicon substrate is well known. Specifically, in the conventional method, the sacrifice layer is dry-etched with using an etching gas composed of mixture of an anhydrous hydrofluoric acid gas (AHF gas) and a methanol vapor gas. The method is disclosed in JP-A-2006-167849.

The inventors in JP-A-2006-167849 considered a manufacturing method of a semiconductor device for controlling H₂O as a reaction product, and an apparatus for manufacturing the semiconductor device. FIG. 10A is a side view showing the apparatus for manufacturing the semiconductor device, and FIG. 10B is a cross sectional view showing a SOI substrate during an etching step.

The manufacturing apparatus 100 includes a reaction chamber as a vacuum chamber 101. The reaction chamber 101 can accommodates three SOI substrates S1, S2, S3 in a stacking direction. The SOI substrates S1-S3 are spaced apart from each other by a predetermined distance. The SOI substrates S1-S3 face each other. Each substrate S1-S3 has a circular planar shape, i.e., a disk shape.

The reaction chamber 101 includes an introduction port 102 for introducing an etching gas and a discharge port 103 for discharging a reaction product. The etching gas is formed from mixture of the AHF gas and the methanol vapor gas or an ethanol vapor gas. The reaction product is formed by reaction in a dry-etching process.

As shown in FIG. 10B, each SOI substrate S1-S3 has a structure such that a first silicon layer 41 as a support substrate, and embedded oxide film 43 as a sacrifice layer and a second silicon layer 44 are stacked in this order. Further, a silicon oxide film 42 as a sacrifice layer is formed on a backside of the first silicon layer 41. The silicon oxide films 42, 43 are formed in an oxidation step of the second silicon layer 44 when the SOI substrate is manufactured. The silicon oxide film 43 is formed in order to increase rigidity of the SOI substrate S1-S3.

When the etching gas is introduced into the reaction chamber 101 via the introduction port 102, the hydrofluoric acid in the etching gas is chemically reacted with the oxide film made of SiO₂, so that the embedded oxide film 43 and the silicon oxide film 42 are etched. At this time, SiF₄ and H₂O as the reaction product are produced.

However, the water H₂O molecule produced on one of the SOI substrates goes with a convective flow of the etching gas so that the H₂O molecule is adsorbed on a surface of other substrates. Further, the water molecule generated on the substrate arranged on an upper side of the chamber 101 goes down by gravity, and then, the water molecule is adsorbed on the substrate, which is arranged under the upper substrate. Then, as shown in chemical formulas F1 and F2, the water molecule adsorbed on the substrate is reacted with the hydrofluoric acid so that the embedded oxide film 43 is excessively etched.

Specifically, the etching amount of a part, on which the water molecule is adsorbed, is largely different from the etching amount of a part, on which no water molecule is adsorbed. Alternatively, the etching amount of a part, on which the water molecule is largely adsorbed, is largely different from the etching amount of a part, on which the water molecule is adsorbed little. Further, since the water molecule generated on the substrate disposed on the upper side of the chamber 101 is adsorbed on the SOI substrate disposed on the lower side of the chamber 101, the etching amount of the substrate disposed on the lower side is larger than the etching amount of the substrate disposed on the upper side.

2HF+H₂O−>H₃O(+)+HF₂(−) F1

SiO₂+2H₃O(+)+2HF₂(−)−>SiF₄+4H₂O F2

Specifically, as shown in FIG. 10B, since the silicon oxide film 42 is formed on a whole of the backside of the SOI substrate, a large amount of water molecule is generated on the silicon oxide film 42. Accordingly, the adsorb amount of the water molecule generated on the backside of the upper side substrate adsorbed on the lower side SOI substrate is large, so that the embedded oxide film 43 is excessively etched.

### SUMMARY

In view of the above-described problem, it is an object of the present disclosure to provide a manufacturing method of a semiconductor device having a silicon substrate with a sacrifice layer and apparatus for manufacturing a semiconductor device having a silicon substrate with a sacrifice layer. Specifically, an etching accuracy of the semiconductor device is improved.

According to a first aspect of the present disclosure, a manufacturing method for a semiconductor device includes: arranging a plurality of silicon substrates having a sacrifice layer in a reaction chamber in such a manner that surfaces of silicon substrates face each other; introducing an etching gas into the reaction chamber; reacting the etching gas and the sacrifice layer in each silicon substrate so that the sacrifice layer is dry-etched; and arranging a partition member in the reaction chamber to partition a predetermined range between adjacent silicon substrates. The partition member has a property in such a manner that a water molecule hardly penetrates the partition member. The water molecule is a reaction product between the etching gas and the sacrifice layer.

In the above method, since the partition member having the property such that the water molecule hardly penetrates the partition member is arranged to partition the predetermined range between adjacent silicon substrates, the water molecule produced as the reaction product is restricted from moving between the adjacent silicon substrates. Thus, the water molecule does not provide to excessively etch the sacrifice layer, and therefore, the etching amount accuracy is improved.

According to a second aspect of the present disclosure, a manufacturing method for a semiconductor device includes: arranging a plurality of silicon substrates having a sacrifice layer in a reaction chamber in such a manner that surfaces of silicon substrates face each other, wherein the sacrifice layer is disposed on at least one surface of each silicon substrate; introducing an etching gas into the reaction chamber; reacting the etching gas and the sacrifice layer in each silicon substrate so that the sacrifice layer is dry-etched; and arranging a partition member in the reaction chamber to cover a predetermined area of the sacrifice layer of one of the silicon substrates, which is disposed on an upper side from a silicon substrate disposed on a lowest side. The partition member has a property in such a manner that a water molecule hardly penetrates the partition member. The water molecule is a reaction product between the etching gas and the sacrifice layer.

In the above method, the partition member having the property such that the water molecule hardly penetrates the partition member is arranged in the reaction chamber to cover a predetermined area of the sacrifice layer of one of the silicon substrates, which is disposed on an upper side from a silicon substrate disposed on a lowest side. Thus, the water molecule is restricted from being produced on the sacrifice layer of the one of the silicon substrates, which is disposed on an upper side from a silicon substrate disposed on a lowest side. Accordingly, the water molecule produced on the sacrifice layer of the one of the silicon substrates arranged on the upper side is restricted from adsorbing on the silicon substrate arranged on the lower side. Thus, since the water molecule does not provide to excessively etch the sacrifice layer, and therefore, the etching amount accuracy is improved.

According to a third aspect of the present disclosure, a manufacturing apparatus for manufacturing a semiconductor device includes: a reaction chamber for accommodating a plurality of silicon substrates having a sacrifice layer in such a manner that surfaces of the silicon substrates face each other, wherein an etching gas is introduced into the reaction chamber so that the etching gas and the sacrifice layer is reacted, and the sacrifice layer is dry-etched; and a partition member arranged in the reaction chamber to partition a predetermined range between adjacent silicon substrates. The partition member has a property in such a manner that a water molecule hardly penetrates the partition member, and the water molecule is a reaction product between the etching gas and the sacrifice layer.

In the above apparatus, since the partition member having the property such that the water molecule hardly penetrates the partition member is arranged to partition the predetermined range between adjacent silicon substrates, the water molecule produced as the reaction product is restricted from moving between the adjacent silicon substrates. Thus, the water molecule does not provide to excessively etch the sacrifice layer, and therefore, the etching amount accuracy is improved.

According to a fourth aspect of the present disclosure, a manufacturing apparatus for manufacturing a semiconductor device includes: a reaction chamber for accommodating a plurality of silicon substrates having a sacrifice layer in such a manner that surfaces of the silicon substrates face each other, wherein an etching gas is introduced into the reaction chamber so that the etching gas and the sacrifice layer is reacted, and the sacrifice layer is dry-etched; and a partition member arranged in the reaction chamber to cover a predetermined area of the sacrifice layer of one of the silicon substrates, which is disposed on an upper side from a silicon substrate disposed on a lowest side. The sacrifice layer is disposed on at least one surface of each silicon substrate. The partition member has a property in such a manner that a water molecule hardly penetrates the partition member, and the water molecule is a reaction product between the etching gas and the sacrifice layer.

In the above apparatus, the partition member having the property such that the water molecule hardly penetrates the partition member is arranged in the reaction chamber to cover a predetermined area of the sacrifice layer of one of the silicon substrates, which is disposed on an upper side from a silicon substrate disposed on a lowest side. Thus, the water molecule is restricted from being produced on the sacrifice layer of the one of the silicon substrates, which is disposed on an upper side from a silicon substrate disposed on a lowest side. Accordingly, the water molecule produced on the sacrifice layer of the one of the silicon substrates arranged on the upper side is restricted from adsorbing on the silicon substrate arranged on the lower side. Thus, since the water molecule does not provide to excessively etch the sacrifice layer, and therefore, the etching amount accuracy is improved.

### BRIEF DESCRIPTION OF THE DRAWINGS

The above and other objects, features and advantages of the present invention will become more apparent from the following detailed description made with reference to the accompanying drawings. In the drawings:

FIG. 1A is a side view showing a manufacturing apparatus according to a first embodiment, and FIG. 1B is a partially enlarged view showing SOI substrates and a partition element in the apparatus;

FIG. 2 is an upper view showing the manufacturing apparatus in FIG. 1A;

FIG. 3A is a side view showing a manufacturing apparatus according to a second embodiment, and FIG. 3B is a partially enlarged view showing SOI substrates and a dummy silicon substrate in the apparatus;

FIG. 4A is a graph showing experimental results, FIG. 4B is a diagram showing a prior art apparatus, and FIG. 4C is a diagram showing a present apparatus;

FIG. 5A is a side view showing a manufacturing apparatus according to a modification of the second embodiment, and FIG. 5B is a partially enlarged view showing SOI substrates and a dummy silicon substrate in the apparatus;

FIG. 6A is a side view showing a manufacturing apparatus according to a third embodiment, and FIG. 6B is a partially enlarged view showing a SOI substrate and a tray in the apparatus;

FIG. 7A is a side view showing a manufacturing apparatus according to a fourth embodiment, and FIG. 7B is a plan view showing a dummy substrate in the apparatus;

FIG. 8A is a side view showing a manufacturing apparatus according to a modification of the fourth embodiment, and FIG. 8B is a plan view showing a dummy substrate in the apparatus;

FIG. 9A is a side view showing a manufacturing apparatus according to a fifth embodiment, and FIG. 9B is a plan view showing a SOI substrate and a dummy substrate in the apparatus;

FIG. 10A is a side view showing a manufacturing apparatus according to a prior art, and FIG. 10B is a cross sectional view showing SOI substrates during an etching process;

FIG. 11 is a side view showing a manufacturing apparatus according to a modification of the first embodiment; and

FIG. 12 is a side view showing a manufacturing apparatus according to a second modification of the second embodiment.

### DETAILED DESCRIPTION

### First Embodiment

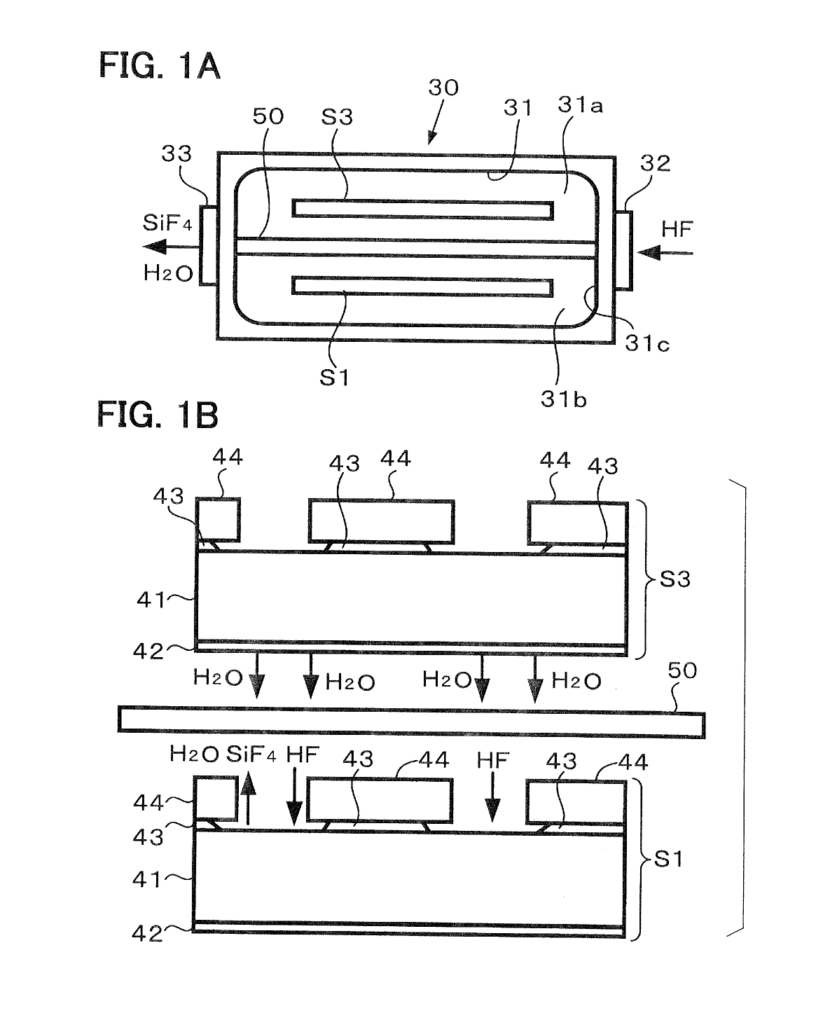

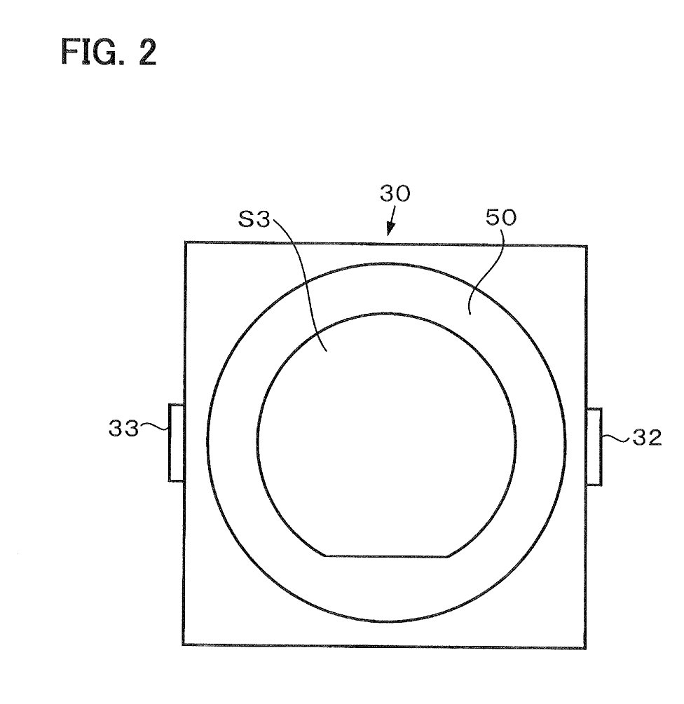

FIG. 1A is a side view showing a manufacturing apparatus according to a first embodiment, and FIG. 1B is a partially enlarged view showing SOI substrates and a partition element in the apparatus. FIG. 2 is an upper view showing the manufacturing apparatus in FIG. 1A. In FIG. 1B, the dimensions of the SOI substrates S1, S3 are enlarged from actual dimensions in order to clarify the structure of the substrates S1, S3.

The manufacturing apparatus 30 includes a reaction chamber 31 as a vacuum chamber. The reaction chamber 31 is divided with a partition element 50 into a first reaction chamber 31a and a second reaction chamber 31b. No clearance is formed between the partition element 50 and an inner wall of the reaction chamber 31. Accordingly, the first reaction chamber 31a and the second reaction chamber 32a are not connected to each other since the partition element 50 partitions. The partition element 50 is made of hastelloy (as a registered brand name) or the like, which has excellent corrosion tolerance, and further, does not pass a water molecule therethrough, or passes the water molecule a little.

The SOI substrate S3 is arranged in the upper first reaction chamber 31a, the SOI substrate S1 is arranged in the second reaction chamber 31b. The SOI substrate S1 is arranged in the lower second reaction chamber 31b. The SIO substrate S3 does not contact the inner wall of the first reaction chamber 31a and the surface of the partition element 50. Further, the SIO substrate S1 does not contact the inner wall of the second reaction chamber 31b and the surface of the partition element 50.

Each of the SOI substrates S1, S3 has a first silicon layer 41 as a support substrate, an embedded oxide film 43 disposed on the surface of the first silicon layer 41, a second silicon layer 44 formed on the surface of the embedded oxide film 43, and a silicon oxide film 42 formed on the backside of the first silicon layer 41. The silicon oxide film 42 and the embedded oxide film 43 provide a sacrifice layer. The silicon oxide film 42 is formed on a whole of the backside of the SOI substrate so that the rigidity of the substrate is improved.

First, the SOI substrates S1, S3 are fed into the reaction chamber 31 with using a feeding device (not shown). Next, the AHF gas is mixed to a methanol (i.e., MeOH) vapor gas or an ethanol (C₂H₆O) vapor gas so that the etching gas is formed. The etching gas is introduced into the chamber 101 via the etching gas introduction port 32. Then, the apparatus starts to etch the silicon oxide film 42 and the embedded oxide film 43. The etching process proceeds according to the following chemical formula F3 so that the hydrofluoric acid and the silicon oxide are reacted with each other.

SiO₂+4HF+2MeOH−>SiF₄↑+2H₂O↑+2MeOH↑ F3

As described in the formula F3, the reaction produces H₂O. The water molecule produced on the SOI substrate S3 is moved downward according to gravity. However, as shown in FIG. 1B, since the partition element 50 is disposed between the substrates S1, S3 so that the first and second reaction chambers 31a, 31b are not connected to each other, the water molecule produced on one substrate is not adsorbed on the other substrate.

Specifically, a large amount of water molecules are produced on the silicon oxide film 42 formed on a whole of the backside of the substrate S1, S3, compared with the embedded oxide film 43. Further, the SOI substrate S1 is arranged under the SOI substrate S3, so that the silicon oxide film 42 of the substrate S3 faces the surface of the substrate S1 via the partition element 50. Accordingly, in the prior art apparatus, the water molecule produced on the backside of the substrate S3 may be adsorbed on the embedded oxide film 43 of the substrate S1. However, in the present apparatus, since the partition element 50 is arranged between the substrates S1, S3, the adsorption of the water molecule is completely prevented.

Thus, the water molecule produced on the SOI substrate S3, which is arranged on the upper side in the chamber 31, is not adsorbed on the substrate S1, which is arranged on the lower side in the chamber 31. Thus, the embedded oxide film 43 of the substrate S1 is not excessively etched, so that the etching amount accuracy is improved.

Specifically, when the second silicon layer 44 provides a micro structure, if the embedded oxide film 43 is excessively etched, the operation of the micro structure in the second silicon layer 44 may be damaged. However, in the present apparatus, since the embedded oxide film 43 of the substrate S1 is not excessively etched, the operation of the micro structure in the second silicon layer 44 is not damaged.

For example, when the SOI substrate provides an acceleration sensor, the second silicon layer 44 provides a fixed electrode and a movable electrode, and the movable electrode has a cantilevered structure, if a support portion for supporting the movable electrode is excessively etched, a bottom side of the movable electrode may contact the surface of the first silicon layer 41 according to a weight of the movable electrode itself. Thus, detection accuracy of the acceleration sensor is reduced.

However, when the present apparatus for manufacturing the semiconductor device as the acceleration sensor is used, the support portion for supporting the movable electrode is not excessively etched, and therefore, the bottom of the movable electrode does not contact the surface of the first silicon layer 41. Thus, the detection accuracy of the acceleration sensor is not reduced.

(Modification)

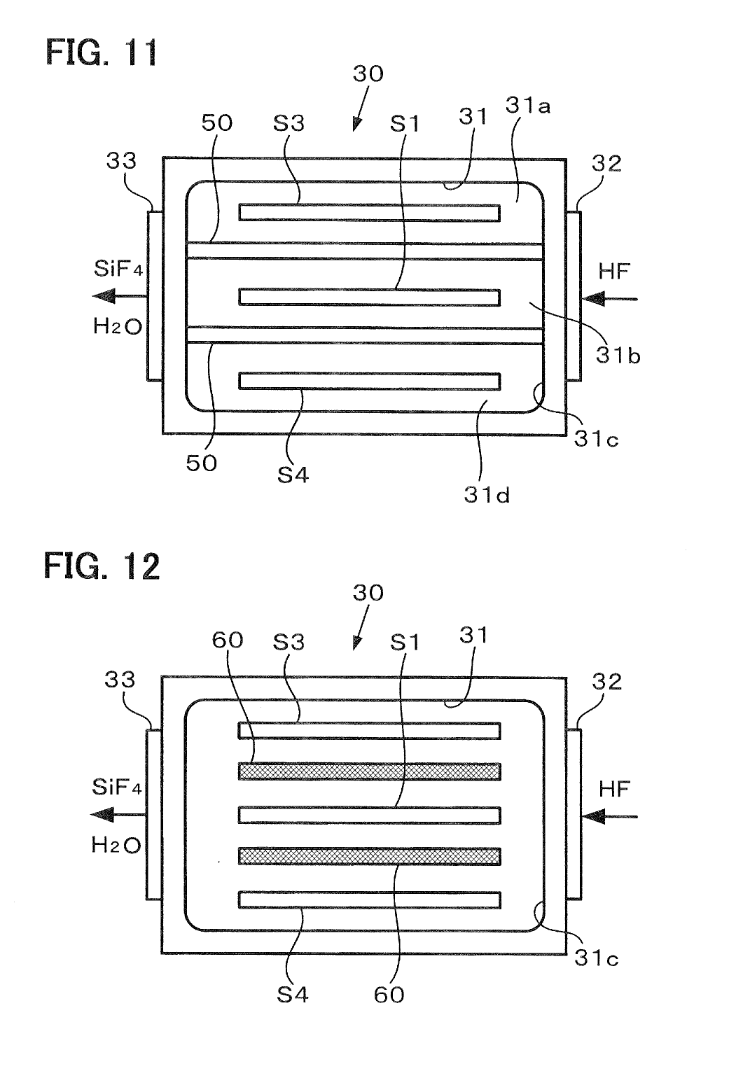

As shown in FIG. 11, the reaction chamber 31 is divided with two partition elements 50 into first to third reaction chambers 31a-31b, 31d. Each chamber 31a-31b, 31d accommodates one SOT substrate S3, S1, S4 so that three SOI substrates S1, S3-S4 can be etched simultaneously. Further, the number of the partition elements 50 may be increased, so that the number of partitioned reaction chambers is increased. Thus, four or more SOI substrates may be etched simultaneously. Specifically, N partition elements are used in the chamber 31 so that the chamber 31 is partitioned to (N+1) chambers. Each partitioned chamber accommodates one SOI substrate, so that (N+1) substrates are etched simultaneously.

### Second Embodiment

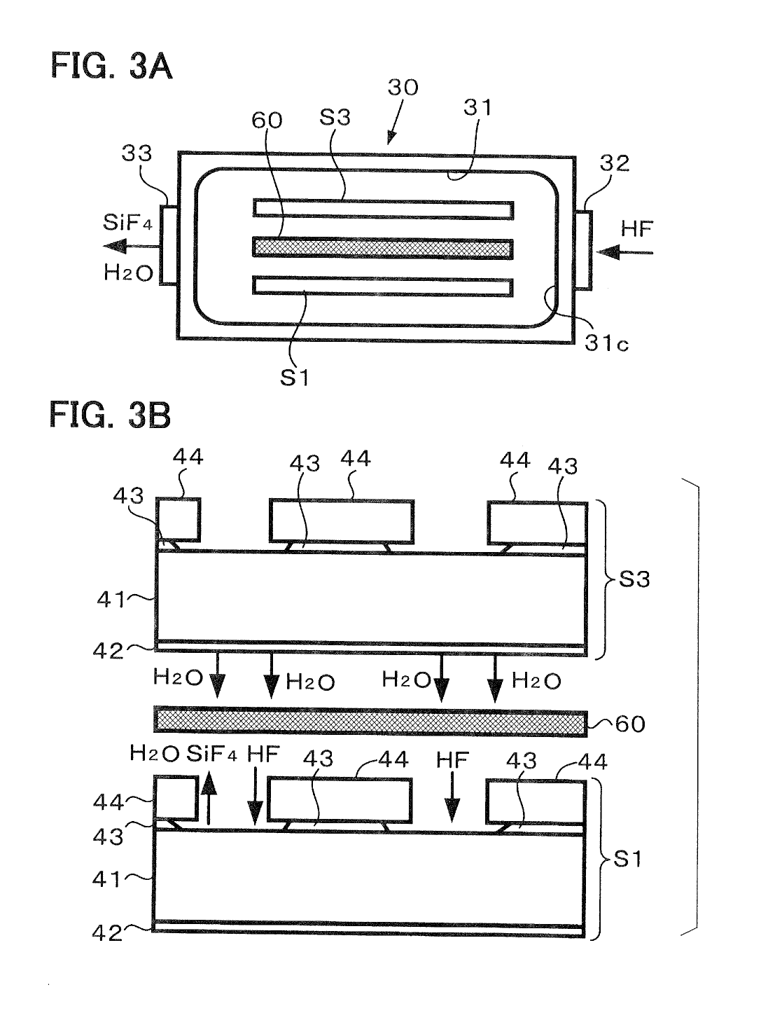

FIG. 3A is a side view showing a manufacturing apparatus according to a second embodiment, and FIG. 3B is a partially enlarged view showing SOI substrates and a dummy silicon substrate in the apparatus;

A manufacturing apparatus according to the present embodiment includes a dummy silicon substrate, which is arranged between two adjacent SOI substrates. As shown in FIG. 3A, the dummy silicon substrate 60 is arranged between the SOI substrates S1, S3. No silicon oxide film is not formed on both sides of the dummy silicon substrate 60. The dimensions of the dummy silicon substrate 60 is equal to the dimensions of the SOI substrates S1, S3 as an etching object.

The dummy silicon substrate 60 together with the SOI substrates S1, S3 is fed (i.e., delivered) in the reaction chamber 31 with using a feeding device. The SOI substrates S1, S3 and the dummy silicon substrate 60 are arranged in an up-down direction in the reaction chamber 31. The SOI substrates S1, S3 and the dummy silicon substrate 60 are spaced apart from each other by a predetermined distance. Specifically, although three SOI substrates may be fed in the reaction chamber 31, one of the substrates at a center side is replaced to the dummy silicon substrate 60, and then, they are fed into the chamber 31.

Thus, since the dummy silicon substrate 60 is arranged between two SOI substrates S1, S3, the water molecule produced on the substrate S3 in the etching process is restricted from going downward by the dummy silicon substrate 60.

Accordingly, since the embedded oxide film 43 of the SOI substrate S1 arranged on the lower side of the chamber 31 is not excessively etched, the etching amount accuracy is improved.

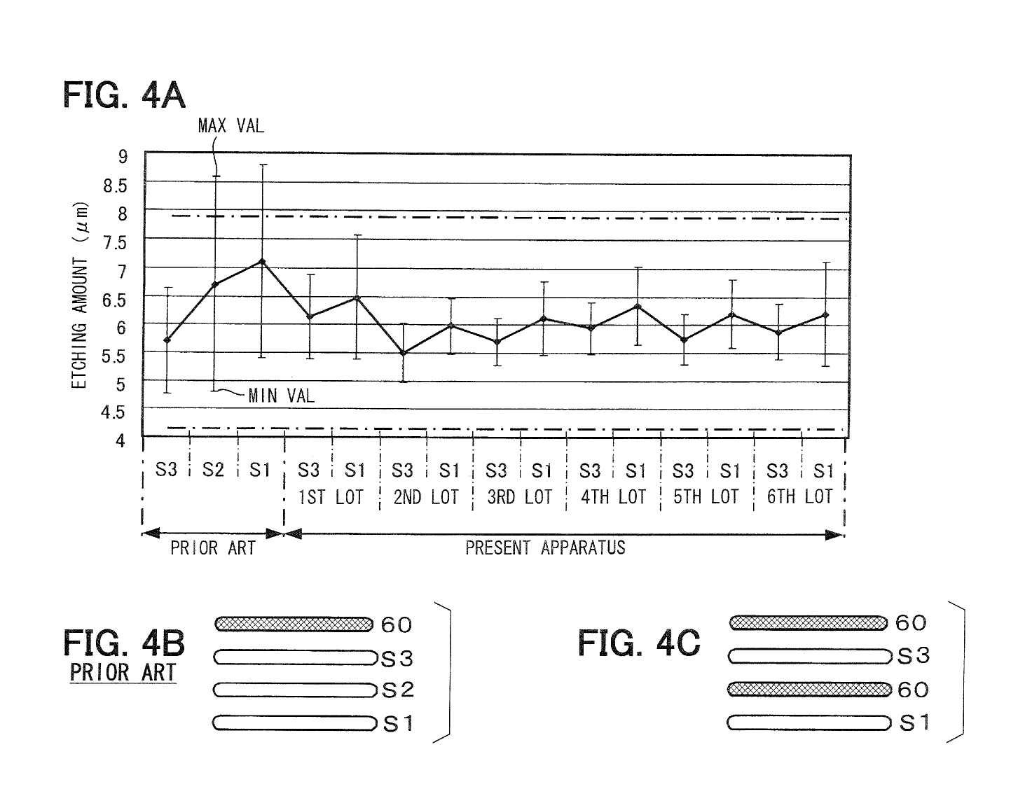

The present inventors execute an experiment in order to evaluate the effects of the dummy silicon substrate 60. FIG. 4A is a graph showing experimental results, FIG. 4B is a diagram showing a prior art apparatus, and FIG. 4C is a diagram showing a present apparatus.

As shown in FIG. 4B, in the prior art apparatus, the SOI substrates S1-S3 are arranged in this order in the up-down direction. Further, the dummy silicon substrate 60 is arranged over the SOI substrates S1-S3. AS shown in FIG. 4C, in the present apparatus, the dummy silicon substrate 60 is arranged between the substrates S1, S3, and further, one more dummy silicon substrate 60 is also arranged over the substrate S3. The structure of the substrates S1-S3 are the same as the substrate in FIG. 1B. The manufacturing apparatus can accommodate four substrates.

The etching gas including mixture of the AHF gas and the vapor of methanol is introduced from the introduction port 32, and then, the silicon oxide film 42 and the embedded oxide film 43 are etched. The etching amount of the embedded oxide film 43 in each of the SOI substrates S1-S3 is measured. Further, the maximum value and the minimum value of the etching amount of each substrate S1-S3 are measured, and the average of the etching amount is calculated. The measurements of the etching amount in the present embodiment is executed with using six lots. Each lot includes the substrates S1-S3. Each one lot is etched, and then, the etching amount of each lot is measured.

As a result, as shown FIG. 4A, the variation of substrates S1-S3, i.e., variation of the average of the etching amount of each substrate, in the present embodiment is smaller than the prior art. Specifically, in the present embodiment, the average of the variation of the etching amount from the first lot to the sixth lot is 6.02±1.01 micrometers. In the prior art, the average of the variation of the etching amount is 7.08±2.65 micrometers. Thus, the average of variation of the etching amount in the present apparatus is smaller by 1.64 micrometers than the prior art.

Further, the variation of the etching amount in the same substrate, i.e., the difference between the maximum value and the minimum value in the same substrate in the present embodiment is smaller than the prior art.

Thus, when the dummy silicon substrate is arranged between the substrates S1, S3, the control accuracy of the etching amount is improved.

### (Modifications)

Further, as shown in FIG. 12, two dummy silicon substrates 60 may be arranged between two adjacent SOI substrates S3, S1, S4, respectively, and then three SOI substrates S3, S1, S4 are etched simultaneously. Further, three or more dummy silicon substrates 60 may be arranged between two adjacent SOI substrates among four or more substrates so that four or more substrates are etched simultaneously. Specifically, (M−1) dummy silicon substrates 60 may be arranged between M SOI substrates, respectively, so that M substrates are etched simultaneously.

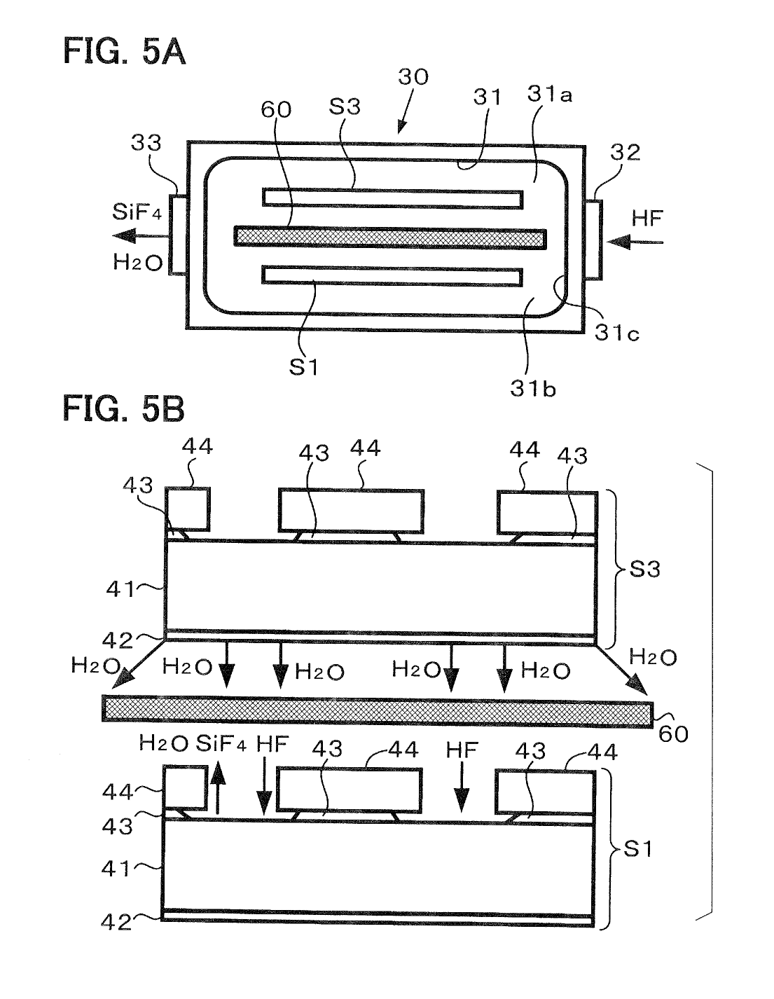

Alternatively, if the water molecule produced on the upper SOI substrate flows around the edge of the dummy silicon substrate, and bypasses the dummy silicon substrate, as shown in FIG. 5, the substrate area of the dummy silicon substrate may be larger than the SOI substrate so that the bypassing of the water molecule is restricted.

When the region, in which the etching amount is varied, is specified, it is not always necessary to prepare the dummy silicon substrate having the same dimensions and the same shape as the SOI substrate. For example, the dummy silicon substrate having the dimensions and the shape corresponding to the specified region may be prepared.

The dummy silicon substrate may be replaced to a plate member made of material other than silicon. The material is selected to have excellent corrosion resistance such as hastelloy, and the material does not produce reaction product such as water, which reacts with the etching gas and negatively affects the etching process.

### Third Embodiment

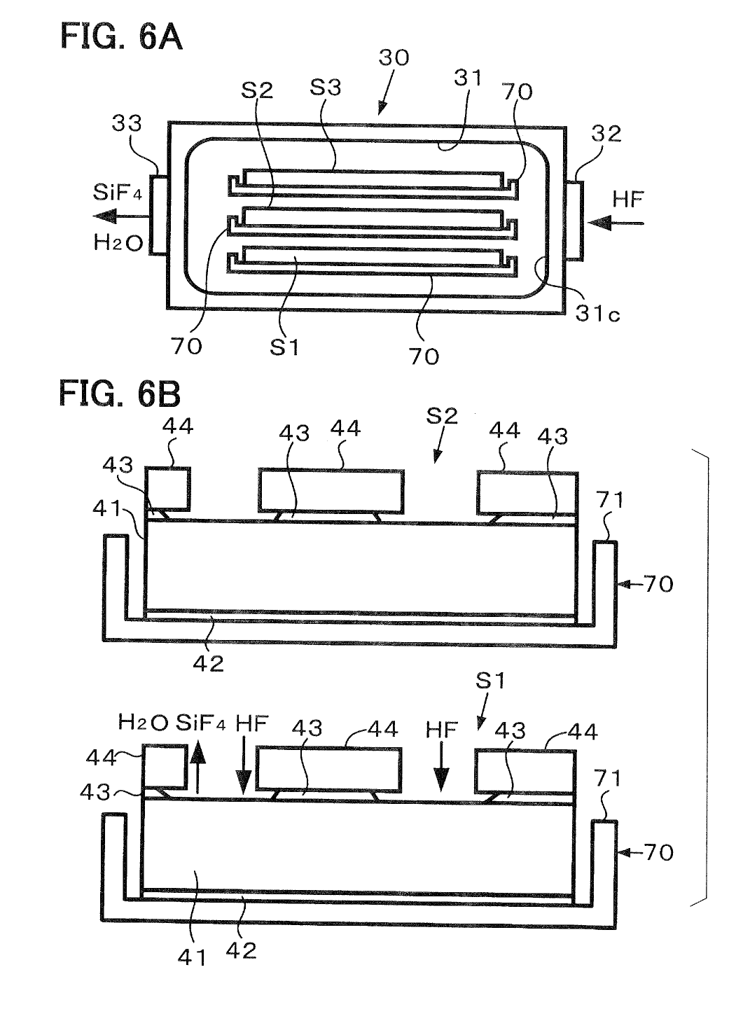

Next, FIGS. 6A and 6B show a manufacturing apparatus for manufacturing a semiconductor device. FIG. 6A is a side view showing the manufacturing apparatus according to a third embodiment, and FIG. 6B is a partially enlarged view showing a SOT substrate and a tray in the apparatus.

The manufacturing apparatus includes a tray for mounting the SOI substrate thereon. As shown in FIGS. 6A and 6B, each substrate S1-S3 is mounted on the tray 70. The tray 70 has the dimensions, which are capable of mounting the SOI substrate on the surface of the tray 70. A circumferential wall 71 is continuously formed at an outer periphery of the tray 70. Specifically, the SOI substrate mounted on the tray 70 has a backside, which contacts the surface of the tray 70. An edge of the substrate is surrounded with the circumferential wall 71. The tray 70 is made of material such as hastelloy, which has excellent corrosion resistance and does not produce water even if the material reacts with the etching gas.

Under a condition that each SOI substrate is mounted on the tray 70, the substrate with the tray 70 is transported to the reaction chamber 31. Alternatively, the tray 70 may be arranged in the reaction chamber preliminary, and then, the substrate is transported to the reaction chamber 31, and then, the substrate is mounted on the tray 70. Alternatively, in some cases, the tray 70 may not have the circumferential wall 71, and the tray 70 may have a plate shape without a wall when the magnitude of the variation of the etching amount is not so large.

Thus, since each substrate S1-S3 is accommodated on the tray 70, the water molecule produced on the upper SOI substrate caused by the reaction with the etching gas is restricted from moving on the lower SOI substrate. Specifically, since the backside of the SOI substrate contacts the surface of the tray 70, the silicon oxide film 42 disposed on the backside of the substrate does not produce the water molecule.

Accordingly, since the lower SOI substrate is not excessively etched, the etching accuracy is improved.

Here, when each SOI substrate is mounted on the tray 70, two or more substrates are etched simultaneously.

### Fourth Embodiment

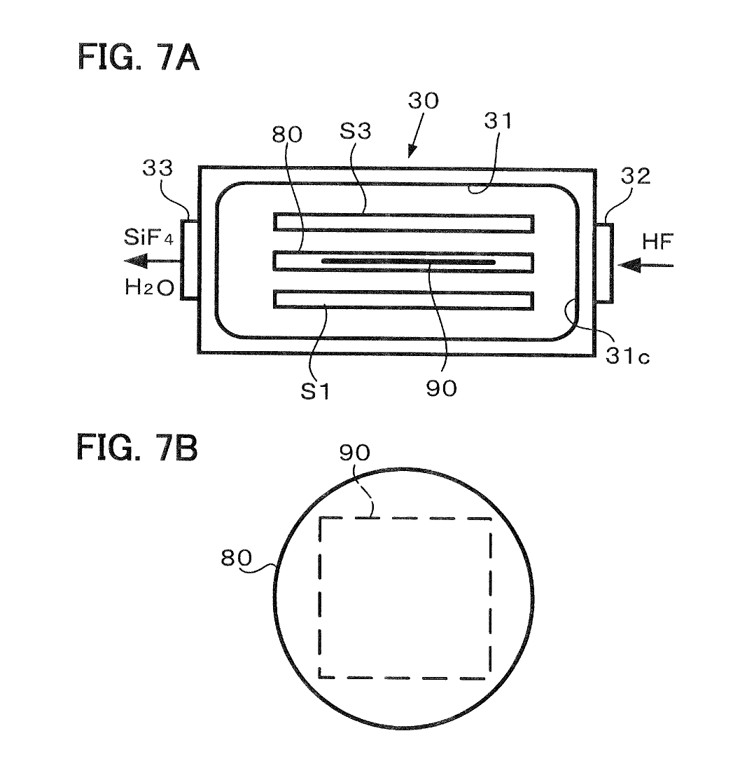

Next, FIGS. 7A and 7B show a manufacturing apparatus for manufacturing a semiconductor device. FIG. 7A is a side view showing a manufacturing apparatus according to a fourth embodiment, and FIG. 7B is a plan view showing a dummy substrate in the apparatus.

The manufacturing apparatus includes a plate member having a heater, which is arranged between the substrates. As shown in FIGS. 7A and 7B, the heater 90 is embedded in the plate member 80 having the shape corresponding to the SOI substrate. The plate member 80 is made of material having high heat conductivity such as stainless steel. In the present embodiment, the heater 90 has a rectangular plate shape. The heater 90 is controlled by a heat controller (not shown). The heater controller controls the heater 90 to generate heat so that the plate member 80 is heated by the heater 90. The heat generated by the heater 90 conducts the SOI substrates S1, S3, so that the heat evaporates the water molecule adsorbed on the substrates S1, S3. Thus, since the water molecule is evaporated from the surface of the substrates S1, S3, the progress of etching caused by reaction between the adsorbed water molecule and the hydrofluoric acid is restricted.

The water molecule produced on the substrates S1, S3 is restricted from moving downwardly by the plate member 80. Further, even if the water molecule is adsorbed on the substrate S1, the adsorbed water molecule is evaporated by the heat generated from the plate member 80. Thus, the accuracy of the etching amount is much improved.

The heater 90 is a sheath heater, a cartridge or the like. The sheath heater has a structure such that a heating wire having a coil shape is inserted into a metal pipe and insulation powder is filled and sealed into the pipe so as to isolate between the pipe and the heating wire. Thus, the sheath heater generates heat by energizing the heating wire. The cartridge heater has a structure such that a heating wire is winded around a bobbin made of in-organic insulation material such as magnesia so as to form a coil, the heating wire is inserted into a metal sheath, and in-organic insulation powder is filled in the sheath.

### (Modifications)

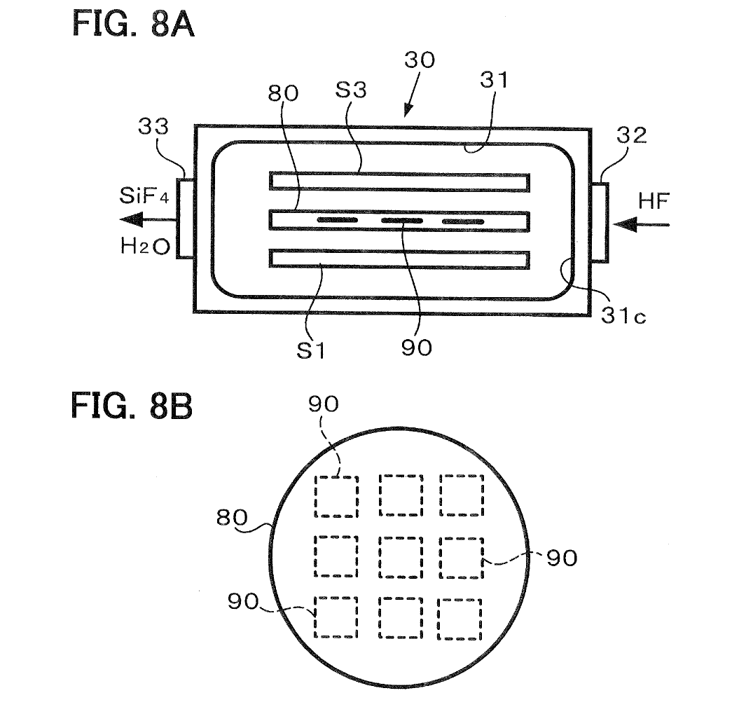

As shown in FIGS. 8A and 8B, multiple heaters 90 may be embedded in the plate member 80. Alternatively, the arrangement of the heater 90 may be changed in order to heat a region, on which the adsorption amount of water molecules is relatively large. Alternatively, the heating temperature of the heater 90 may be controlled according to the adsorption amount of the water molecule, which adsorbs on a certain region. Alternatively, the plate member 80 may be formed from the heater itself.

### Fifth embodiment

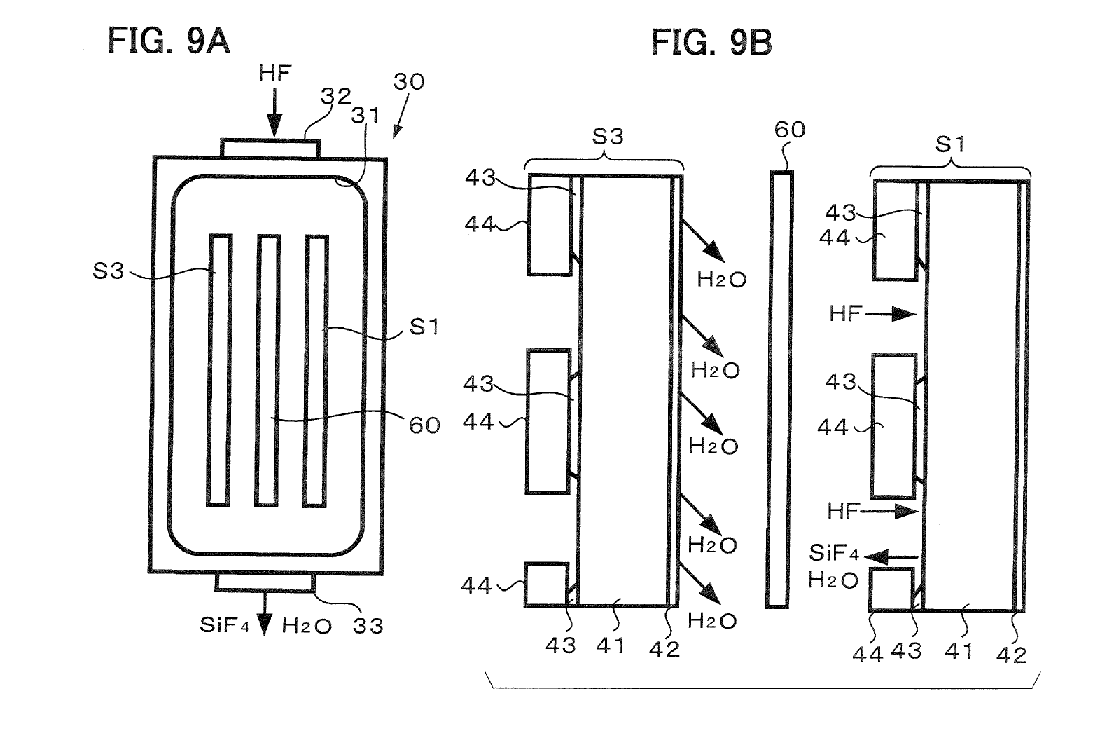

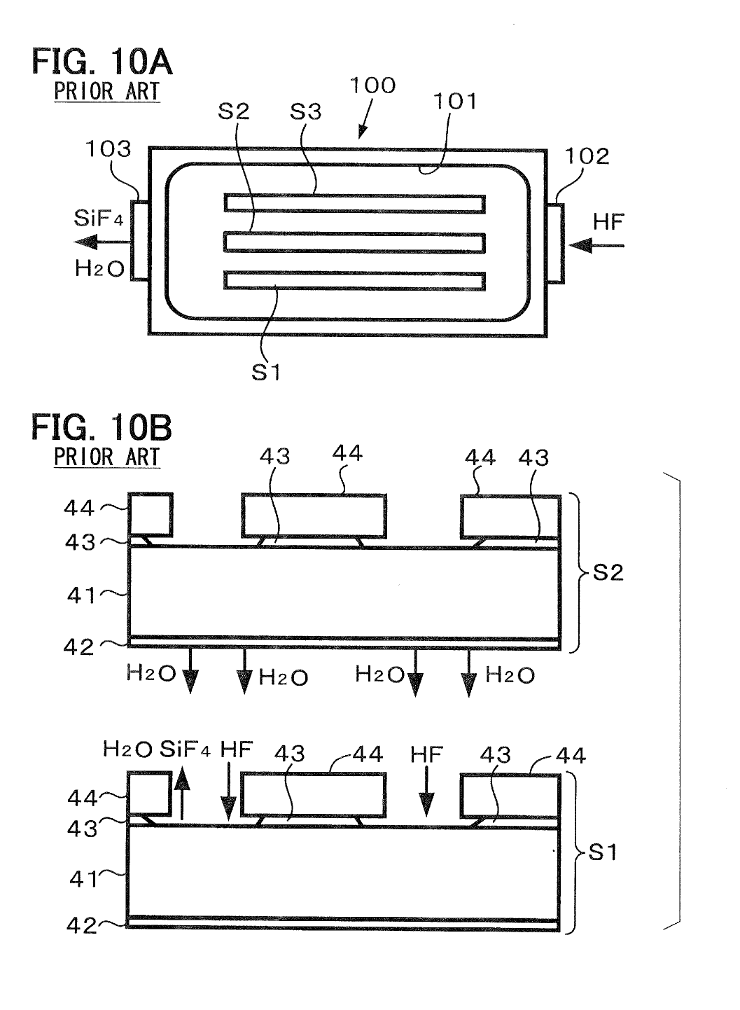

Next, FIGS. 9A and 9B show a manufacturing apparatus for manufacturing a semiconductor device. FIG. 9A is a side view showing a manufacturing apparatus according to a fifth embodiment, and FIG. 9B is a plan view showing a SOI substrate and a dummy substrate in the apparatus.

In the manufacturing apparatus, the SOI substrates S1, S3 and the dummy silicon substrate 60 are arranged vertically. As shown in FIGS. 9A and 9B, the manufacturing apparatus 30 includes the introduction port 32 disposed on the upside of the apparatus 30 and the discharge port 33 disposed on the downside. The substrates S1, S3 are arranged in the reaction chamber 31 vertically. The dummy silicon substrate 60 is arranged between the substrates S1, S3 vertically.

Since the substrates S1, S3 are vertically arranged in the chamber 31 so that the water molecule produced from the substrate S1, S3 is moved downwardly along with the gravitational force direction, the water molecule produced from one substrate is not easily adsorbed on the other substrate. Here, the dummy silicon substrate 60 according to the modifications in the second embodiment may be used for the present embodiment.

### Other Embodiments

The adsorption layer made of material having a property for adsorbing a water molecule may be formed on the dummy silicon substrate. For example, the adsorption layer is made of material such as zirconium alloy, silica-gel, alumina-gel, silica-alumina-gel, and zeolite. When the dummy silicon substrate with the adsorption layer is used, the water molecule produced from each SOI substrate is adsorbed on the adsorption layer. Thus, the excess etching is restricted, and the etching accuracy is improved. Alternatively, the above embodiments and modifications may be combined. Further, in the present embodiment, the semiconductor device is the acceleration sensor. Alternatively, the device may be a pressure sensor, a flow sensor, and the like. Alternatively, the device may have a structure having small sized structure and high dimensional accuracy. For example, the device may be a micro structure such as a MEMS (i.e., micro-electro-mechanical systems).

The above disclosure has the following aspects.

According to a first aspect of the present disclosure, a manufacturing method for a semiconductor device includes: arranging a plurality of silicon substrates having a sacrifice layer in a reaction chamber in such a manner that surfaces of silicon substrates face each other; introducing an etching gas into the reaction chamber; reacting the etching gas and the sacrifice layer in each silicon substrate so that the sacrifice layer is dry-etched; and arranging a partition member in the reaction chamber to partition a predetermined range between adjacent silicon substrates. The partition member has a property in such a manner that a water molecule hardly penetrates the partition member. The water molecule is a reaction product between the etching gas and the sacrifice layer.

In the above method, since the partition member having the property such that the water molecule hardly penetrates the partition member is arranged to partition the predetermined range between adjacent silicon substrates, the water molecule produced as the reaction product is restricted from moving between the adjacent silicon substrates. Thus, the water molecule does not provide to excessively etch the sacrifice layer, and therefore, the etching amount accuracy is improved.

Alternatively, the sacrifice layer may be disposed on at least one surface of each silicon substrate. In this case, if there is no partition member, the water molecule produced on the one surface of an upper silicon substrate is easily adsorbed on the surface of a lower silicon substrate. However, since the water molecule produced on the one surface of the upper silicon substrate is blocked by the partition member, the water molecule is restricted from adsorbing on the surface of the lower silicon substrate. Thus, the water molecule does not provide to excessively etch the sacrifice layer, and therefore, the etching amount accuracy is improved.

Alternatively, the partition member may have an area of one surface, which faces one of the silicon substrates. The area of the one surface of the partition member is larger than a surface area of the one of the silicon substrates. In this case, the water molecule produced as the reaction product is restricted from moving between the adjacent silicon substrates. Thus, the water molecule does not provide to excessively etch the sacrifice layer, and therefore, the etching amount accuracy is improved.

Alternatively, the partition member may partition between adjacent silicon substrates so that two partitioned rooms are formed. The two partitioned rooms are not connected to each other. In this case, the water molecule produced as the reaction product does not move between the adjacent silicon substrates. Thus, the water molecule does not provide to excessively etch the sacrifice layer, and therefore, the etching amount accuracy is improved.

Alternatively, the partition member may be a silicon substrate, which does not produce the water molecule. In this case, it is not necessary to prepare a special member for partitioning between adjacent silicon substrates. Accordingly, the manufacturing cost of the semiconductor device is reduced.

Alternatively, the partition member may adsorb the water molecule. In this case, since the partition member can adsorb the water molecule produced as the reaction product, the adsorption amount of the water molecule on the silicon substrate is much reduced.

Alternatively, the reaction chamber may include an introduction port and a discharge port. The introduction port introduces the etching gas into the reaction chamber. The discharge port discharges the reaction product from the reaction chamber. The introduction port is disposed on an upper side of the reaction chamber, and the discharge port is disposed on a lower side of the reaction chamber. The silicon substrates are arranged vertically in the reaction chamber so that the silicon substrates are aligned in a horizontal direction. In this case, the water molecule produced as the reaction product is displaced in the gravitational force direction. Accordingly, adsorption amount of the water molecule on the silicon substrate is much reduced.

Alternatively, the partition member may include a heater therein. In this case, the water molecule adsorbed on the silicon substrate is evaporated by heat generated by the heater. Further, the water molecule adsorbed on the partition member is also evaporated. Accordingly, adsorption amount of the water molecule on the silicon substrate is much reduced.

Alternatively, the sacrifice layer may be a silicon oxide film, and the etching gas may include an anhydrous hydrofluoric acid gas. In this case, the water molecule may be produced easily by reaction between the anhydrous hydrofluoric acid gas and the oxide silicon. However, since the partition member restricts the water molecule from adsorbing on the silicon substrate, the etching amount accuracy is improved.

According to a second aspect of the present disclosure, a manufacturing method for a semiconductor device includes: arranging a plurality of silicon substrates having a sacrifice layer in a reaction chamber in such a manner that surfaces of silicon substrates face each other, wherein the sacrifice layer is disposed on at least one surface of each silicon substrate; introducing an etching gas into the reaction chamber; reacting the etching gas and the sacrifice layer in each silicon substrate so that the sacrifice layer is dry-etched; and arranging a partition member in the reaction chamber to cover a predetermined area of the sacrifice layer of one of the silicon substrates, which is disposed on an upper side from a silicon substrate disposed on a lowest side. The partition member has a property in such a manner that a water molecule hardly penetrates the partition member. The water molecule is a reaction product between the etching gas and the sacrifice layer.

In the above method, the partition member having the property such that the water molecule hardly penetrates the partition member is arranged in the reaction chamber to cover a predetermined area of the sacrifice layer of one of the silicon substrates, which is disposed on an upper side from a silicon substrate disposed on a lowest side. Thus, the water molecule is restricted from being produced on the sacrifice layer of the one of the silicon substrates, which is disposed on an upper side from a silicon substrate disposed on a lowest side. Accordingly, the water molecule produced on the sacrifice layer of the one of the silicon substrates arranged on the upper side is restricted from adsorbing on the silicon substrate arranged on the lower side. Thus, since the water molecule does not provide to excessively etch the sacrifice layer, and therefore, the etching amount accuracy is improved.

According to a third aspect of the present disclosure, a manufacturing apparatus for manufacturing a semiconductor device includes: a reaction chamber for accommodating a plurality of silicon substrates having a sacrifice layer in such a manner that surfaces of the silicon substrates face each other, wherein an etching gas is introduced into the reaction chamber so that the etching gas and the sacrifice layer is reacted, and the sacrifice layer is dry-etched; and a partition member arranged in the reaction chamber to partition a predetermined range between adjacent silicon substrates. The partition member has a property in such a manner that a water molecule hardly penetrates the partition member, and the water molecule is a reaction product between the etching gas and the sacrifice layer.

In the above apparatus, since the partition member having the property such that the water molecule hardly penetrates the partition member is arranged to partition the predetermined range between adjacent silicon substrates, the water molecule produced as the reaction product is restricted from moving between the adjacent silicon substrates. Thus, the water molecule does not provide to excessively etch the sacrifice layer, and therefore, the etching amount accuracy is improved.

According to a fourth aspect of the present disclosure, a manufacturing apparatus for manufacturing a semiconductor device includes: a reaction chamber for accommodating a plurality of silicon substrates having a sacrifice layer in such a manner that surfaces of the silicon substrates face each other, wherein an etching gas is introduced into the reaction chamber so that the etching gas and the sacrifice layer is reacted, and the sacrifice layer is dry-etched; and a partition member arranged in the reaction chamber to cover a predetermined area of the sacrifice layer of one of the silicon substrates, which is disposed on an upper side from a silicon substrate disposed on a lowest side. The sacrifice layer is disposed on at least one surface of each silicon substrate. The partition member has a property in such a manner that a water molecule hardly penetrates the partition member, and the water molecule is a reaction product between the etching gas and the sacrifice layer.

In the above apparatus, the partition member having the property such that the water molecule hardly penetrates the partition member is arranged in the reaction chamber to cover a predetermined area of the sacrifice layer of one of the silicon substrates, which is disposed on an upper side from a silicon substrate disposed on a lowest side. Thus, the water molecule is restricted from being produced on the sacrifice layer of the one of the silicon substrates, which is disposed on an upper side from a silicon substrate disposed on a lowest side. Accordingly, the water molecule produced on the sacrifice layer of the one of the silicon substrates arranged on the upper side is restricted from adsorbing on the silicon substrate arranged on the lower side. Thus, since the water molecule does not provide to excessively etch the sacrifice layer, and therefore, the etching amount accuracy is improved.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A manufacturing method for a semiconductor device comprising:
arranging a plurality of silicon substrates having a sacrifice layer in a reaction chamber in such a manner that surfaces of silicon substrates face each other;
introducing an etching gas into the reaction chamber;
reacting the etching gas and the sacrifice layer in each silicon substrate so that the sacrifice layer is dry-etched; and
arranging a partition member in the reaction chamber to partition a predetermined range between adjacent silicon substrates,
wherein the partition member has a property in such a manner that a water molecule hardly penetrates the partition member, and
wherein the water molecule is a reaction product between the etching gas and the sacrifice layer.

2. A manufacturing method for a semiconductor device comprising:
arranging a plurality of silicon substrates having a sacrifice layer in a reaction chamber in such a manner that surfaces of silicon substrates face each other, wherein the sacrifice layer is disposed on at least one surface of each silicon substrate;
introducing an etching gas into the reaction chamber;
reacting the etching gas and the sacrifice layer in each silicon substrate so that the sacrifice layer is dry-etched; and
arranging a partition member in the reaction chamber to cover a predetermined area of the sacrifice layer of one of the silicon substrates, which is disposed on an upper side from a silicon substrate disposed on a lowest side,
wherein the partition member has a property in such a manner that a water molecule hardly penetrates the partition member, and
wherein the water molecule is a reaction product between the etching gas and the sacrifice layer.

3. The manufacturing method according to claim 1,
wherein the sacrifice layer is disposed on at least one surface of each silicon substrate.

4. The manufacturing method according to claim 1,
wherein the partition member has an area of one surface, which faces one of the silicon substrates, and
wherein the area of the one surface of the partition member is larger than a surface area of the one of the silicon substrates.

5. The manufacturing method according to claim 4,
wherein the partition member partitions between adjacent silicon substrates so that two partitioned rooms are formed, and
wherein the two partitioned rooms are not connected to each other.

6. The manufacturing method according to claim 1,
wherein the partition member is a silicon substrate, which does not produce the water molecule.

7. The manufacturing method according to claim 1,
wherein the partition member adsorbs the water molecule.

8. The manufacturing method according to claim 1,
wherein the reaction chamber includes an introduction port and a discharge port,
wherein the introduction port introduces the etching gas into the reaction chamber,
wherein the discharge port discharges the reaction product from the reaction chamber,
wherein the introduction port is disposed on an upper side of the reaction chamber, and the discharge port is disposed on a lower side of the reaction chamber, and
wherein the silicon substrates are arranged vertically in the reaction chamber so that the silicon substrates are aligned in a horizontal direction.

9. The manufacturing method according to claim 1,
wherein the partition member includes a heater therein.

10. The manufacturing method according to claim 1,
wherein the sacrifice layer is a silicon oxide film, and
wherein the etching gas includes an anhydrous hydrofluoric acid gas.

11. A manufacturing apparatus for manufacturing a semiconductor device comprising:
a reaction chamber for accommodating a plurality of silicon substrates having a sacrifice layer in such a manner that surfaces of the silicon substrates face each other, wherein an etching gas is introduced into the reaction chamber so that the etching gas and the sacrifice layer is reacted, and the sacrifice layer is dry-etched; and
a partition member arranged in the reaction chamber to partition a predetermined range between adjacent silicon substrates,
wherein the partition member has a property in such a manner that a water molecule hardly penetrates the partition member, and
wherein the water molecule is a reaction product between the etching gas and the sacrifice layer.

12. A manufacturing apparatus for manufacturing a semiconductor device comprising:
a reaction chamber for accommodating a plurality of silicon substrates having a sacrifice layer in such a manner that surfaces of the silicon substrates face each other, wherein an etching gas is introduced into the reaction chamber so that the etching gas and the sacrifice layer is reacted, and the sacrifice layer is dry-etched; and
a partition member arranged in the reaction chamber to cover a predetermined area of the sacrifice layer of one of the silicon substrates, which is disposed on an upper side from a silicon substrate disposed on a lowest side,
wherein the sacrifice layer is disposed on at least one surface of each silicon substrate,
wherein the partition member has a property in such a manner that a water molecule hardly penetrates the partition member, and
wherein the water molecule is a reaction product between the etching gas and the sacrifice layer.

13. The manufacturing apparatus according to claim 11,
wherein the sacrifice layer is disposed on at least one surface of each silicon substrate.

14. The manufacturing apparatus according to claim 11,
wherein the partition member has an area of one surface, which faces one of the silicon substrates, and
wherein the area of the one surface of the partition member is larger than a surface area of the one of the silicon substrates.

15. The manufacturing apparatus according to claim 14,
wherein the partition member partitions between adjacent silicon substrates so that two partitioned rooms are formed, and
wherein the two partitioned rooms are not connected to each other.

16. The manufacturing apparatus according to claim 11,
wherein the partition member is a silicon substrate, which does not produce the water molecule.

17. The manufacturing apparatus according to claim 11,
wherein the partition member adsorbs the water molecule.

18. The manufacturing apparatus according to claim 11,
wherein the reaction chamber includes an introduction port and a discharge port,
wherein the introduction port introduces the etching gas into the reaction chamber,
wherein the discharge port discharges the reaction product from the reaction chamber,
wherein the introduction port is disposed on an upper side of the reaction chamber, and the discharge port is disposed on a lower side of the reaction chamber, and
wherein the silicon substrates are arranged vertically in the reaction chamber so that the silicon substrates are aligned in a horizontal direction.

19. The manufacturing apparatus according to claim 11,
wherein the partition member includes a heater therein.

20. The manufacturing apparatus according to claim 11,
wherein the sacrifice layer is a silicon oxide film, and
wherein the etching gas includes an anhydrous hydrofluoric acid gas.
